(19) United States
(12) Patent Application Publication
(10) Pub. No.: US 2024/0384391 A1
(43) Pub. Date: Nov. 21, 2024

(54) DISPLAY DEVICE MANUFACTURING APPARATUS

(71) Applicant: Samsung Display Co., LTD., Yongin-si (KR)

(72) Inventors: JUNYOUNG LEE, Yongin-si (KR); JEONGWEON SEO, Yongin-si (KR); JUNWOO YOU, Yongin-si (KR); JEONGHO HWANG, Yongin-si (KR)

(21) Appl. No.: 18/650,270

(22) Filed: Apr. 30, 2024

(30) Foreign Application Priority Data
May 16, 2023 (KR) 10-2023-0063266

(51) Int. Cl. C23C 14/04; H10K 71/16

(52) U.S. Cl. CPC C23C 14/042; H10K 71/166

(57) ABSTRACT

A display device manufacturing apparatus includes a display panel, a mask provided on the display panel, and including a frame which includes a first surface and a second surface opposed to the first surface, and in which a mask opening penetrating the first surface and the second surface is defined, and a support disposed in the mask opening, extended to the frame, and including a third surface having a same plane as that of the first surface and a fourth surface opposed to the third surface, and an application unit which moves along a direction parallel to a first direction in which the support extends and includes a first roller contacting the third surface, a second roller contacting the first surface, and a spray member disposed between the first and second rollers in a second direction crossing the first direction, and spraying a resin to the mask opening.

This application claims priority to Korean Patent Application No. 10-2023-0063266, filed on May 16, 2023, and all the benefits accruing therefrom under 35 U.S.C. § 119, the content of which in its entirety is herein incorporated by reference.

### BACKGROUND

### 1. Field

The disclosure herein relates to a display device manufacturing apparatus, and more particularly, to a display device manufacturing apparatus capable of securing application uniformity of an application material.

### 2. Description of the Related Art

Multimedia electronic devices such as televisions, mobile phones, tablet computers, navigation systems, or game consoles may include a display device for displaying an image, and electronic parts that perform various functions. As electronic devices become higher in performance and smaller in thickness, a display device and electronic parts become larger in capacity and more highly integrated.

As an electronic device becomes thinner, for example, research is being conducted on an apparatus and method capable of applying a cover panel onto a display panel of the display device, and securing thickness uniformity of an application material.

### SUMMARY

The disclosure provides a display device manufacturing apparatus capable of securing thickness uniformity of an application material to be applied.

An embodiment of the inventive concept provides a display device manufacturing apparatus including a stage on which a display panel is provided, a mask provided on the display panel, and including a frame which includes a first surface and a second surface opposed to the first surface and facing the stage, and in which a mask opening penetrating the first surface and the second surface is defined, and a support disposed in the mask opening, extended to the frame, and including a third surface having a same plane as a plane of the first surface and a fourth surface opposed to the third surface, and an application unit moving along a direction parallel to a first direction in which the support extends. The application unit includes a first roller in contact with the third surface, a second roller in contact with the first surface, and a spray member disposed between the first roller and the second roller in a second direction crossing the first direction, and spraying a resin to the mask opening.

In an embodiment, a lowermost end of the spray member may be spaced apart from planes extending from the first surface and from the second surface.

In an embodiment, the support may overlap the center portion of the mask opening.

In an embodiment, the first roller may be provided in plural, and the first rollers may be arranged along the second direction.

In an embodiment, the second roller may be provided in plural, and the second rollers may be disposed apart from each other with the first roller therebetween.

In an embodiment, the support may be arranged in plurality, the first roller may be provided in plural, and the first rollers may be arranged along the second direction to be respectively in contact with the supports.

In an embodiment, the mask may further include an auxiliary support disposed in the mask opening, and extending to the frame along the second direction, and a width of the auxiliary support in the first direction is equal to or greater than a width of the support in the second direction.

In an embodiment, the resin sprayed by the spray member may overlap at least a portion of the first surface and at least a portion of the support.

In an embodiment, the mask may include metal.

In an embodiment, at least one of the first roller or the second roller may include polyimide-based plastic.

In an embodiment, a thickness of the support in a third direction may be equal to a thickness of the frame in the third direction.

In an embodiment, the spray member may be provided in plural, and the spray members may be disposed apart from each other in the second direction with the first roller therebetween.

In an embodiment, the display device manufacturing apparatus may further include a curing unit curing the applied resin.

In an embodiment, the display device manufacturing apparatus may further include a mask stage disposed between the stage and the mask to support the mask.

In an embodiment, a stage opening for accommodating the display panel may be defined in the mask stage, and the stage opening may overlap the mask opening.

In an embodiment of the inventive concept, a display device manufacturing apparatus includes a mask including a frame in which a mask opening penetrating a first surface and a second surface facing each other is defined, and a support disposed in the mask opening to be extended to the frame along a first direction to divide the mask opening into a first opening and a second opening arranged along a second direction crossing the first direction, and an application unit moving along the first direction on the first surface of the mask. The application unit includes a first roller in contact with one surface of the support, a first spray member overlapping the first opening, and a second spray member spaced apart from the first spray member in the second direction with the first roller therebetween, and overlapping the second opening.

In an embodiment, the application unit may further include a plurality of second rollers each being in contact with the second surface of the frame, and spaced apart from each other in the second direction with the first spray member and the second spray member therebetween.

In an embodiment, a lowermost end of each of the first and second spray members may be spaced apart from planes extending from the one surface of the support and from the second surface of the frame.

In an embodiment, the support and the first roller may be each provided in plural.

In an embodiment, the mask may further include an auxiliary support disposed in the mask opening, and extending along the second direction to the frame, and a width of the auxiliary support in the first direction may be equal to or greater than a width of the support in the second direction.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a schematic view illustrating an embodiment of a part of a display device according to the inventive concept;

FIG. 2 is a perspective view of an embodiment of a display device manufacturing apparatus according to the inventive concept;

FIGS. 3A to 3C are plan views of an embodiment of a mask according to the inventive concept;

FIG. 4 is a perspective view of an embodiment of a display device manufacturing apparatus according to the inventive concept; and

FIGS. 5A to 5E are cross-sectional views of an embodiment of a display device manufacturing apparatus illustrating operations of a method for manufacturing a display device according to the inventive concept.

### DETAILED DESCRIPTION

In this specification, when a component (or region, layer, portion, etc.) is referred to as “on”, “connected”, or “coupled” to another component, it means that it is placed/connected/coupled directly on the other component or a third component can be disposed between them.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Hereinafter, a display panel in an embodiment of the inventive concept and a method for manufacturing the same will be described with reference to the drawings.

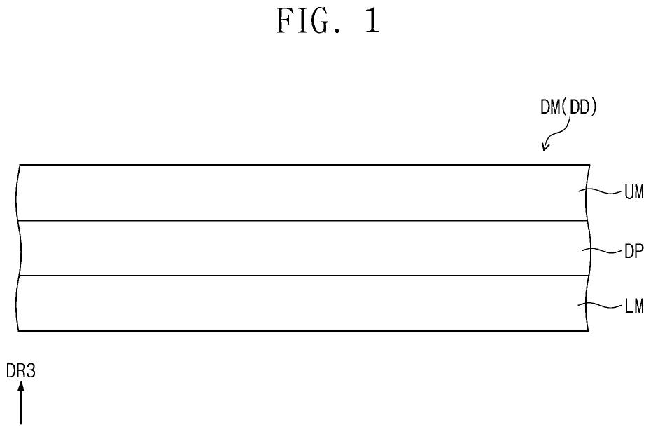

FIG. 1 is a schematic view illustrating an embodiment of a part of a display device according to the inventive concept.

A display device DD may generate an image, and sense an external input. The display device DD may include a display module DM, and electronic parts.

The display module DM may include a display panel DP, an upper member UM, and a lower member LM. The upper member UM may be a window, an optical layer, or an adhesive layer, and may be provided as a plurality of layers without being limited to what is illustrated in the drawing. The lower member LM may be a cover panel or a support member, and may be provided as a plurality of layers without being limited to what is illustrated in the drawing.

FIG. 1 simply illustrates only the display panel DP, the upper member UM, and the lower member LM in a stack structure of the display module DM, but the display module DM is not limited thereto. Hereinafter, the window and the adhesive layer will be described in an embodiment of the upper member UM, the cover panel and the adhesive layer will be described in an embodiment of the lower member LM, but the upper member UM and the lower member LM are not limited thereto.

The display panel DP may display an image in response to an electrical signal. The display panel DP in an embodiment may be a light-emitting display panel, but is not specially limited thereto. In an embodiment, the display panel DP may be an organic light-emitting display panel, an inorganic light-emitting display panel, or a quantum dot light-emitting display panel, for example. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc.

The window may be disposed on the display panel DP. The window may cover the display panel DP to protect the display panel DP from an external impact and a scratch. The window may be bonded to the display panel DP through an adhesive layer.

The window may have a single-layered or multi-layered structure. In an embodiment, the window may include a plurality of plastic films bonded with an adhesive, or include a glass film and a plastic film bonded with an adhesive, for example. The window may further include a functional layer such as an anti-fingerprint layer, a phase control layer, or a hard coating layer disposed on a transparent film.

The cover panel may be disposed on the display panel DP. The cover panel may be disposed apart from the window with the display panel DP therebetween. The cover panel may have a single-layered or multi-layered structure. The cover panel may not only dissipate heat but also protect the display panel DP from an external impact or an interference transferred to the display panel DP. The cover panel may be directly formed on the display panel DP.

The adhesive layer may be disposed between the window and the display panel DP, or between the cover panel and the display panel DP. The adhesive layer may have a single-layered or multi-layered structure. The adhesive layer may include an optical clear resin. However, a material of each adhesive layer is not limited thereto, and the adhesive layer may include a typical adhesive or bonding agent. In an embodiment, the adhesive layer may include a pressure sensitive adhesive (“PSA”), or an optically clear adhesive (“OCA”), for example. In addition, the inventive concept is not limited thereto, and the adhesive layer may include an optically clear adhesive film.

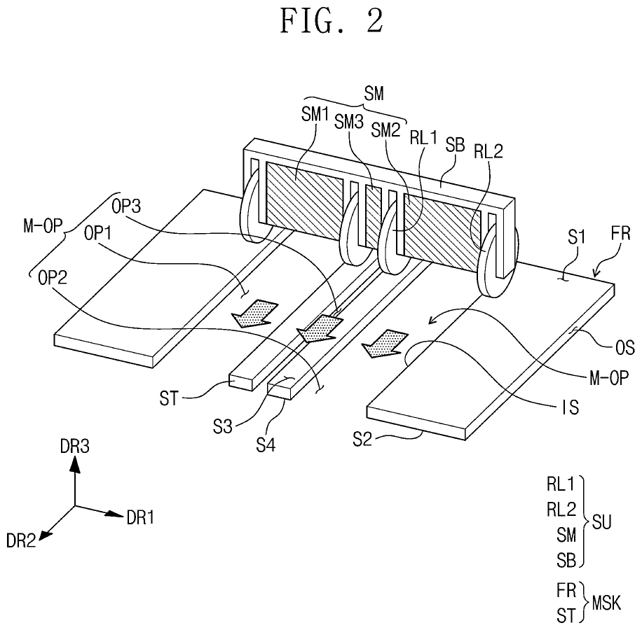

FIG. 2 is a perspective view of an embodiment of a display device manufacturing apparatus according to the inventive concept.

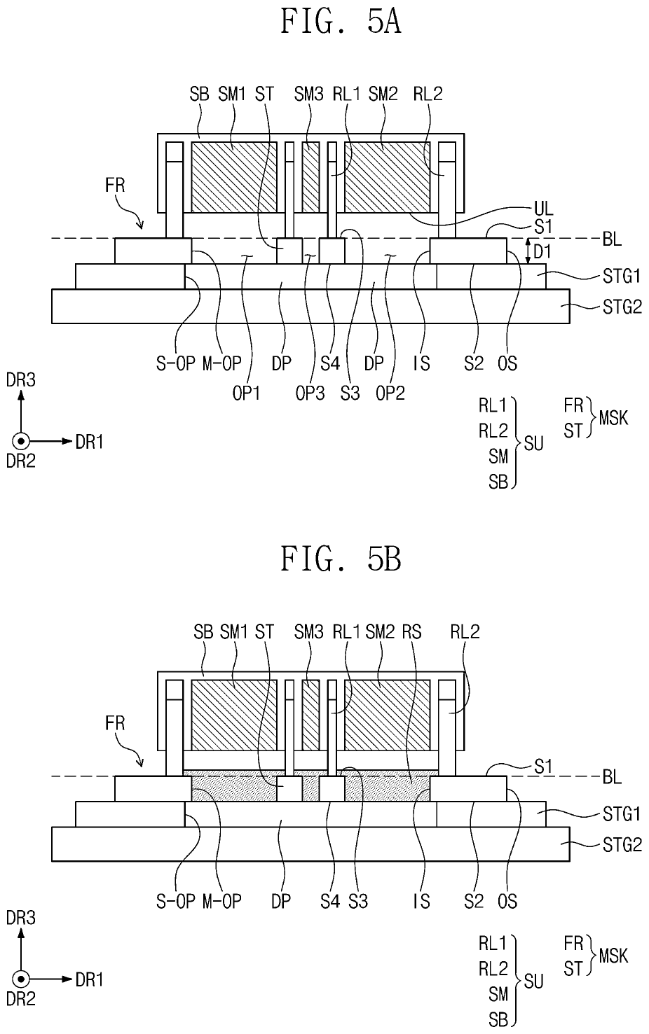

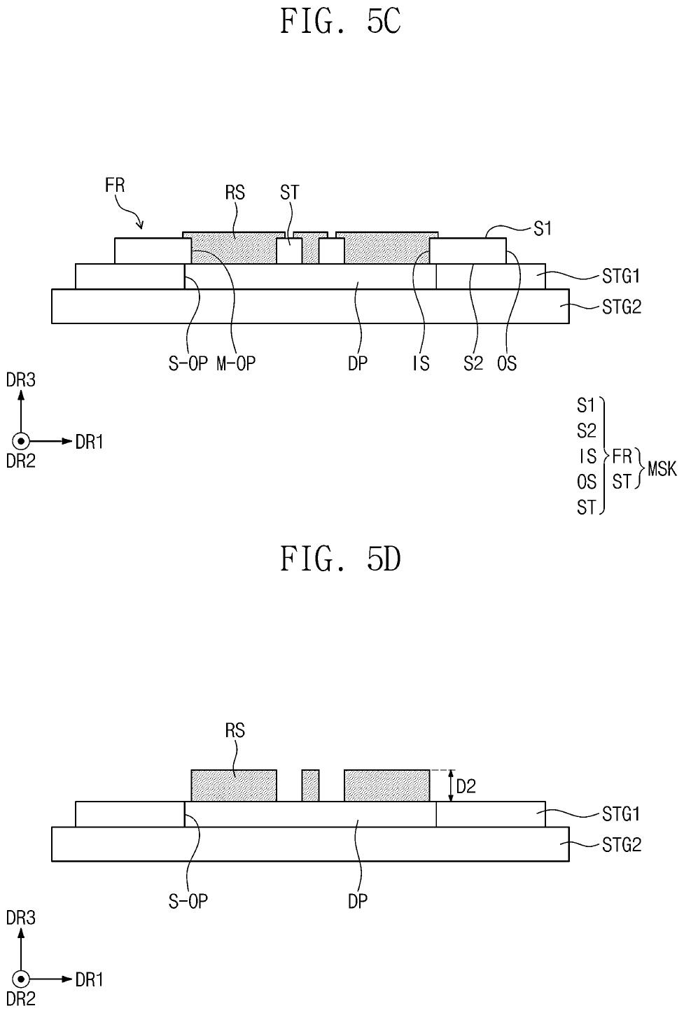

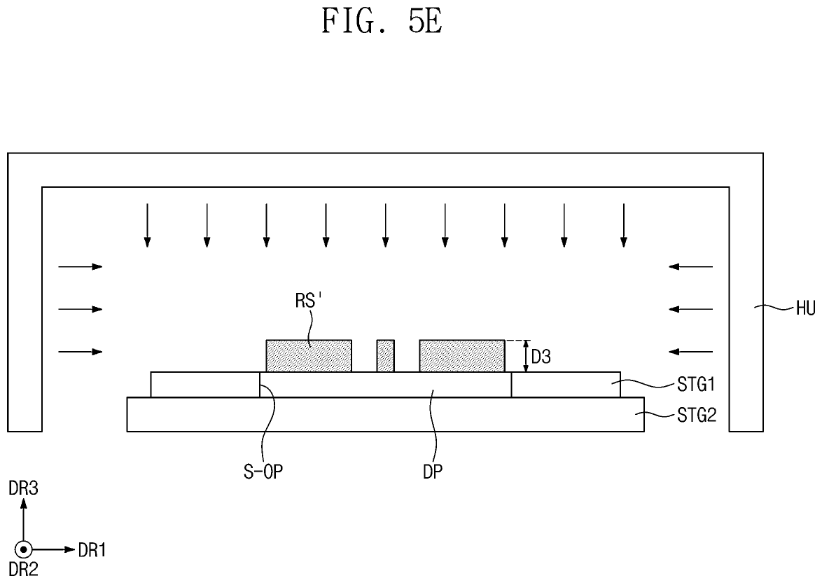

The display device manufacturing apparatus in an embodiment of the inventive concept includes a mask MSK and an application unit SU. The mask MSK and the application unit SU according to the inventive concept may be disposed on a display panel DP (refer to FIG. 5A).

In an embodiment, an application target may be the display panel DP (refer to FIG. 1), and an application material may be a resin. In addition, the application material may be applied onto the application target to form an upper member UM (refer to FIG. 1) or a lower member LM (refer to FIG. 1) described above. However, the application target and the application material are respectively limited to the display panel DP (refer to FIG. 1) and the resin, and are not limited to any particular embodiment.

The application unit SU in an embodiment of the inventive concept may include rollers RL1 and RL2 and a spray member SM.

The rollers RL1 and RL2 may move forward or backward along an upper surface of the mask MSK. Referring to FIG. 2, the rollers RL1 and RL2 may mover forward or backward along a second direction DR2. It is illustrated in the drawing that the rollers RL1 and RL2 may move forward or backward along the second direction DR2, but a moving direction of the rollers RL1 and RL2 is not limited thereto, and the rollers RL1 and RL2 may move forward or backward in a direction different from the second direction DR2.

The rollers RL1 and RL2 may be provided in plural. A first roller RL1 of the plurality of rollers RL1 and RL2 may contact a support ST, and a second roller RL2 of the plurality of rollers RL1 and RL2 may contact a frame FR. Specifically, the first roller RL1 of the plurality of rollers RL1 and RL2 may contact a third surface S3 of the support ST, and the second roller RL2 of the plurality of rollers RL1 and RL2 may contact a first surface S1 of the frame FR.

The first roller RL1 and the second roller RL2 may be respectively in contact with portions different from each other in the mask MSK. The first roller RL1 and the second roller RL2 may be rollers having one rotational axis, but the inventive concept is not limited thereto. The first roller RL1 and the second roller RL2 may be provided as rollers respectively having different rotational axes, but the inventive concept is not limited thereto.

The first roller RL1 may contact the support ST to prevent the support ST from being lifted off along a third direction DR3. This makes it possible for an application material to be uniformly applied onto the application target when the application material is applied onto a mask opening M-OP through the spray member SM to be described later. The second roller RL2 may contact the frame FR to prevent the frame FR from being lifted up along the third direction DR3, and to prevent changes in the shape of the mask MSK due to an external force applied to the mask MSK as well as the roller.

The first roller RL1 may be provided in plural. In an embodiment, the number of the plurality of first rollers RL1 may correspond to the number of the support ST, for example. The plurality of first rollers RL1 may be disposed apart from each other in the second direction DR2, which is a direction crossing the moving direction of the application unit SU.

The second roller RL2 may be provided in plural. The plurality of second rollers RL2 may be disposed apart from each other with the first roller RL1 therebetween. The second rollers RL2 may be disposed apart from each other with the first roller RL1 therebetween so that the second roller RL2 may each move forward or backward in a state of being in contact with the upper surface of the frame FR, and thus the first roller RL1 may be prevented from deviating from a preset position. Through this, the second roller RL2 may make the first roller RL1 and the second roller RL2 uniformly press the mask MSK, and make a distance of the spray member SM of the application unit SU and the mask opening M-OP constant. This makes it possible to achieve the application uniformity of the application material.

In an embodiment, the first roller RL1 and the second roller RL2 may be provided to have the same thickness as each other in a first direction DR1. In addition, a thickness of the first roller RL1 and a thickness of the second roller RL2 may respectively correspond to a thickness of the support ST and a thickness of the first surface S1. It is illustrated in the drawing that the first roller RL1 and the second roller RL2 have the same thicknesses, but the inventive concept is not limited thereto. The thickness of the first roller RL1 may be smaller than or equal to the thickness of the second roller RL2, but the inventive concept is not limited thereto. The thickness of the first roller RL1 is greater than the thickness of the second roller RL2, but the inventive concept is not limited thereto.

The spray member SM may spray the application material onto the mask opening M-OP. The spray member SM may spray the application material onto the mask opening M-OP to fill the mask opening M-OP with the application material.

The spray member SM may be provided in plural, and the plurality of spray members SM may be disposed between the plurality of rollers RL1 and RL2. The plurality of spray members SM may be placed between the plurality of rollers RL1 and RL2 spaced apart from each other in the first direction DR1. Some of the plurality of spray members SM may be disposed apart from each other in the first direction DR1 with the first roller RL1 therebetween. In addition, some of the plurality of spray members SM may be placed between the plurality of first rollers RL1.

The plurality of spray members SM may include a first spray member SM1 and a second spray member SM2. The first spray member SM1 may overlap a first opening OP1 to be described later, and the second spray member SM2 may overlap a second opening OP2 to be described later. The first spray member SM1 may spray the application material to the first opening OP1, and the second spray member SM2 may spray the application material to the second opening OP2 to be described later.

The spray member SM may further include a third spray member SM3. The third spray member SM3 may overlap a third opening OP3 to be described later. The third spray member SM3 may spray the application material to the third opening OP3.

FIG. 2 illustrates the third spray member SM3 of the spray member SM, but an embodiment of the inventive concept is not limited to what is illustrated in the drawing. The third spray member SM3 may be omitted, and the inventive concept is not limited thereto.

In an embodiment, a lowermost end UL (refer to FIG. 5A) of the spray member SM may be disposed higher than lowermost ends of the first roller RL1 and the second roller RL2. Accordingly, the durability of the mask MSK and the application unit SU may be achieved by preventing interference between the support ST or the mask MSK, and the spray member SM.

The application unit SU may include a support body SB coupled to the rollers RL1 and RL2 and the spray member SM. The support body SB may be provided separable from the rollers RL1 and RL2 and the spray member SM, but the inventive concept is not limited thereto. The support body SB may be provided integrally with the rollers RL1 and RL2 and the spray member SM, but the inventive concept is not limited thereto.

The mask MSK in an embodiment of the inventive concept may include the frame FR and the support ST. The mask opening M-OP may be defined in the frame FR, and the support ST may be extended to the frame FR, while overlapping the mask opening M-OP.

The frame FR may include a first surface S1, a second surface S2, a third surface IS, and a fourth surface OS. The first surface S1 may define an upper surface of the mask MSK. The first surface S1 may be defined by the first direction DR1 and the second direction DR2. The second surface S2 may define a lower surface of the mask MSK. The second surface S2 may be opposed to the first surface S1. The mask opening M-OP may be defined in the frame FR. The third surface IS may define an inner surface of the frame FR. In addition, the third surface IS may define the mask opening M-OP. That is, the mask opening M-OP may penetrate the first surface S1 and the second surface S2 and be defined by the third surface IS. The third surface IS may extend in a thickness direction (e.g., a third direction DR3) of the frame FR to be extended to each of the first surface S1 and the second surface S2. A thickness direction of the frame FR may be a direction parallel to the third direction DR3 crossing each of the first direction DR1 and the second direction DR2. The fourth surface OS may define an outer surface of the frame FR. The fourth surface OS may extend in the thickness direction of the frame FR to be extended to each of the first surface S1 and the second surface S2. Hereinafter, for convenience of description, the third surface IS and the fourth surface OS of the frame FR may be respectively referred to as an inner surface IS and an outer surface OS.

The mask opening M-OP may expose at least a partial region of the display panel DP (refer to FIG. 5A). The region of the display panel DP (refer to FIG. 5A) exposed by the mask opening M-OP may be an application region. A resin sprayed by the application unit SU may be applied onto the display panel DP (refer to FIG. 5A) through the mask opening M-OP. The application region may correspond to a front surface of a cell region. Here, the display panel DP (refer to FIG. 5A) may include at least one cell region. However, this is an illustrative embodiment, and according to design of the application region, the application region may have a smaller area than one cell region, or have an area overlapping a plurality of cell regions, and the inventive concept is not limited thereto.

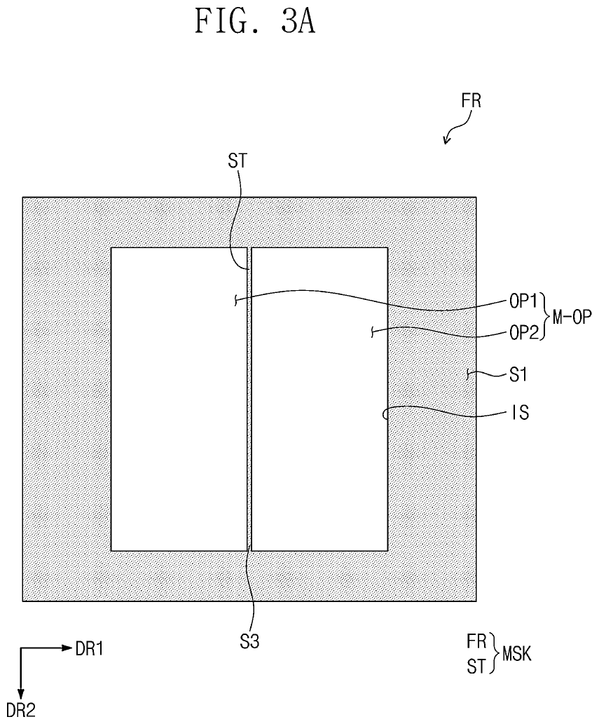

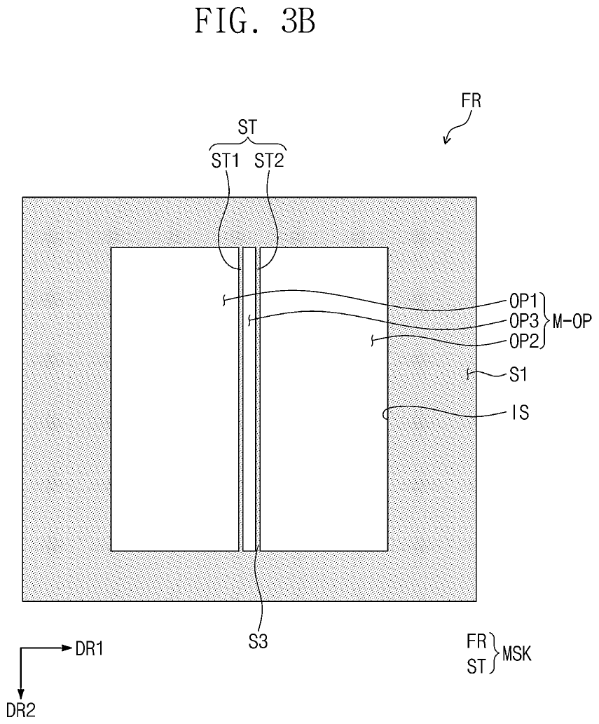

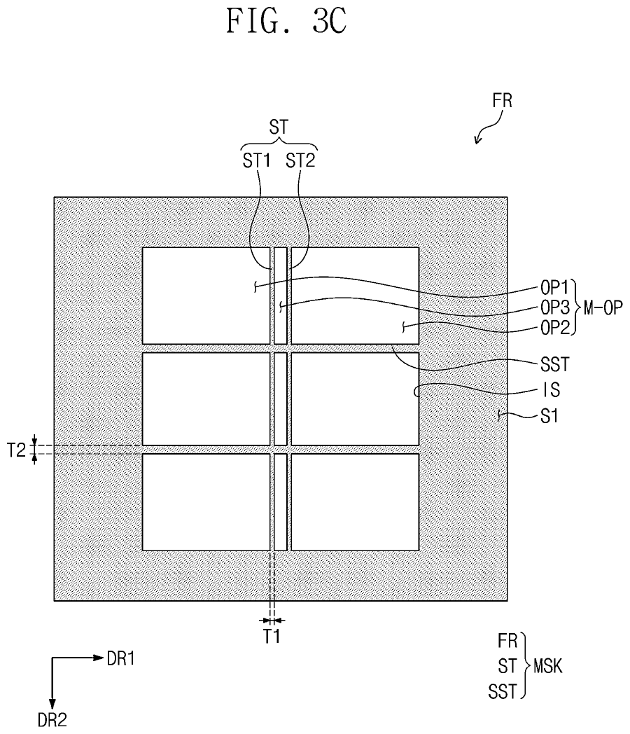

The support ST may be extended to the inner surface IS of the frame FR (refer to FIG. 3B). The support ST may be disposed in the mask opening M-OP. The support ST may be disposed overlapping the center portion of the mask opening M-OP, and a separation distance between the support ST and the mask opening M-OP in the first direction DR1 may be constant, but the inventive concept is not limited thereto. The separation distance between the support ST and the mask opening M-OP in the first direction DR1 may not be constant, and the inventive concept is not limited thereto. The support ST may divide the foregoing mask opening M-OP into the first opening OP1 and the second opening OP2.

The support ST may extend in a direction parallel to the moving direction of the application unit SU. The support ST may extend along the second direction DR2, but an extension direction of the support ST is not limited to the second direction DR2. The support ST may extend in a direction different from the second direction DR2, and the inventive concept is not limited thereto.

The support ST may include a first surface S3 extended to the frame FR, and having the same plane as that of the first surface S1, and a second surface S4 opposed to the first surface S1. Hereinafter, for convenience of description, the first surface S3 of the support ST may be also referred to as the third surface S3, and the second surface S4 of the support ST may be also referred to as the fourth surface S4.

The first roller RL1 described above may contact the third surface S3, and the second roller RL2 may contact the first surface S1. The support ST may contact the first roller RL1 and may be prevented from deviating from the existing design position due to a stress of the mask MSK, e.g., from being lifted off in the third direction DR3. Therefore, the application uniformity of the application material may be secured even in a region adjacent to the support ST.

In addition, collision with the spray member SM may be prevented by preventing a lift-off phenomenon that the support ST is lifted off in the third direction DR3. This makes it possible to ensure the durability of the mask MSK and the application unit SU, and facilitate the maintenance and repair of the mask MSK and the application unit SU.

The mask MSK may include metal. In an embodiment, the mask MSK may include stainless steel (“SUS”). The rollers RL1 and RL2 may include polyimide-based plastic such as Vespel®, for example. Accordingly, a static electricity which may occur due to a contact between the mask MSK and the rollers RL1 and RL2 may be prevented, and thus damage to the mask MSK may be prevented. According to the inventive concept, the durability between the mask MSK and the rollers RL1 and RL2 may be increased, and the positions of the mask MSK and the rollers RL1 and RL2 may be maintained to preset values by preventing an additional external force from being applied to the mask MSK and the rollers RL1 and RL2. Consequently, the application uniformity of the application material onto the application target may be secured.

FIGS. 3A to 3C are plan views of an embodiment of a mask according to the inventive concept.

Referring to FIG. 3A, a support ST may be disposed in a mask opening M-OP. The support ST may have a bar shape extending along the second direction DR2. The mask opening M-OP may be divided into a first opening OP1 and a second opening OP2 along the first direction DR1 by the support ST.

The support ST may overlap the center of the mask opening M-OP. Accordingly, the first opening OP1 and the second opening OP2 may respectively have regions having the same area as each other in a plan view. However, This is an illustrative embodiment, and according to area design of the first opening OP1 and the second opening OP2, the position of the support ST may be variously changed in the mask opening M-OP, and is not limited to any particular embodiment.

A third surface S3 of the support ST may contact a first roller RL1, and a first surface S1 of a frame FR may contact a second roller RL2. The foregoing first spray member SM1 (refer to FIG. 2) may spray a resin to the first opening OP1, and the foregoing second spray member SM2 (refer to FIG. 2) may spray a resin to the second opening OP2.

Referring to FIG. 3B, a plurality of supports ST may be disposed in the mask opening M-OP. The plurality of supports ST may be disposed apart from each other along the first direction DR1.

The plurality of supports ST may divide the mask opening M-OP into a first opening OP1, a second opening OP2, and a third opening OP3. The third opening OP3 may overlap the center of the mask opening M-OP, and the first opening OP1 and the second opening OP2 may be spaced apart from each other in the first direction DR1 with the third opening OP3 therebetween. FIG. 3 illustrates that in a plan view, the first opening OP1 and the second opening OP2 may respectively have regions having the same area as each other, and the third opening OP3 may have a region having a smaller area than that of the first opening OP1 and the second opening OP2, but the inventive concept is not limited thereto. The first opening OP1, the second opening OP2, and the third opening OP3 may have the same area, and the inventive concept is not limited thereto.

The foregoing first spray member SM1 (refer to FIG. 2) may spray a resin to the first opening OP1, the foregoing second spray member SM2 (refer to FIG. 2) may spray a resin to the second opening OP2, and the foregoing third spray member SM3 (refer to FIG. 2) may spray a resin to the third opening OP3.

Unlike a partial region, of an application target, which overlaps the support ST and onto which a resin is not applied, the foregoing third spray member SM3 (refer to FIG. 2) may spray a resin to the third opening OP3, and thus a resin may be disposed in another partial region, of the application target, overlapping the third opening OP3.

Afterwards, during scribing of the partial region, of the application target, which overlaps the support ST and onto which a resin is not applied, a scribing device may be supported in the region, of the application target, which overlaps the third opening OP3 and onto which a resin is applied, scribing of the application target may be smoothly processed, thereby increasing process efficiency and improving product quality.

Referring to FIG. 3C, the support ST may be provided in plural in the mask opening M-OP. In addition, an auxiliary support SST may be disposed in the mask opening M-OP. The plurality of supports ST may be disposed apart from each other in the first direction DR1. The plurality of supports ST may divide the mask opening M-OP into a first opening OP1, a second opening OP2, and a third opening OP3.

The auxiliary support SST may extend along a direction crossing an extension direction of the support ST. The auxiliary support SST may have a bar shape extending along the first direction DR1. The auxiliary support SST may cross the support ST.

A width T2 of the auxiliary support SST in the second direction DR2 may be equal to or greater than a width T1 of the support ST in the first direction DR1. In an embodiment, the width T2 of the auxiliary support SST in the second direction DR2 may be greater than the width T1 of the support ST in the first direction DR1 so that lift-off in the third direction DR3 may be prevented even when there is no additional external force provided in the third direction DR3, for example.

The auxiliary support SST may divide each of the first opening OP1, the second opening OP2, and the third opening OP3. The auxiliary support SST may be provided in plural, and the auxiliary supports SST may be disposed apart from each other along the second direction DR2. The auxiliary supports SST spaced apart from each other may respectively divide each of the first opening OP1, the second opening OP2, and the third opening OP3 into various regions.

A stress applied to the mask MSK may be effectively dispersed through the plurality of supports ST and the plurality of auxiliary supports SST, so that deformation of the mask MSK may be prevented, and durability of the mask MSK may be secured.

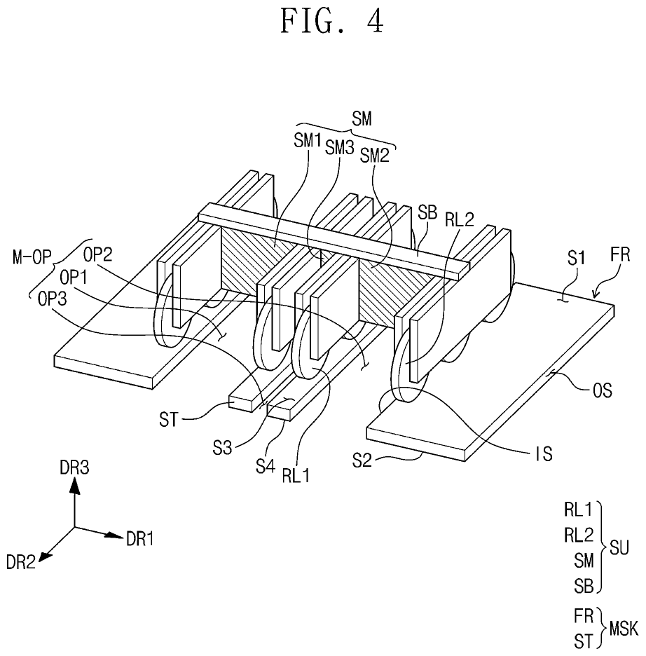

FIG. 4 is a perspective view of an embodiment of a display device manufacturing apparatus according to the inventive concept.

When the display device manufacturing apparatus in FIG. 4 is compared with the display device manufacturing apparatus in FIG. 2, first rollers RL1 and second rollers RL2 may be each arranged along the second direction DR2.

Since a plurality of first rollers RL1 contact the same support ST, the support ST may be effectively prevented from being lifted off along the third direction (i.e., thickness direction) DR3.

Since a plurality of second rollers RL2 are simultaneously in contact with the frame FR, a phenomenon that the mask MSK is lifted off along the third direction DR3 may be effectively prevented, and deformation of the mask MSK due to an external force applied to the mask MSK as well as the rollers may be also effectively prevented.

In addition, since the first roller RL1 and the second roller RL2 of the application unit SU are simultaneously in contact with a wide region of the mask MSK along the second direction DR2 to press the mask MSK in the third direction DR3, flatness of the mask MSK before and after starting application may be increased.

It is only illustrated in the drawing that the plurality of first rollers RL1 and the plurality of second rollers RL2 are respectively arranged along the second direction DR2 on an upper surface of the same support ST and on an upper surface of one side of the frame FR, but the inventive concept is not limited thereto. The plurality of first rollers RL1 may be respectively arranged along the first direction DR1 on the upper surface of the same support ST, and the plurality of second rollers RL2 may be respectively arranged along the first direction DR1 on the upper surface of the one side of the frame FR. However, the inventive concept is not limited thereto.

FIGS. 5A to 5E are cross-sectional views of an embodiment of a display device manufacturing apparatus illustrating operations of a method for manufacturing a display device according to the inventive concept.

The method for manufacturing a display device in an embodiment of the inventive concept may include an operation of disposing a display panel DP on a stage STG2, an operation of disposing a mask stage STG1 and a mask MSK on the stage STG2, an operation of disposing an application unit SU on the mask MSK, an operation of applying, by the application unit SU, an application material RS in an opening of the mask MSK, an operation of removing the mask MSK and the mask stage STG1, and an operation of curing the application material applied onto the display panel DP. A predetermined operation among the operations above may be omitted as desired, and a sequence of the operations is not limited to the order above, and is not limited to any particular embodiment.

FIGS. 5A to 5E illustrate some cross-sectional views of the display device manufacturing apparatus under some operations.

Referring to FIG. 5A, the method for manufacturing a display device in an embodiment of the inventive concept may include an operation of disposing the display panel DP and the mask stage STG1 on the stage STG2, and an operation of disposing the application unit SU on the mask stage STG1. In an embodiment, the display panel DP may be disposed in an opening S-OP of the mask stage STG1.

In the application unit SU, the lowermost end UL of a spray member SM may be spaced apart from a plane BL extending from a position in which a third surface S3 of the support ST and a first roller RL1 contact each other, and a plane BL extending from a position in which a first surface S1 of the frame FR and a second roller RL2 contact each other. The lowermost end UL of the spray member SM may be upwardly spaced apart from the extending plane BL. Since the lowermost end UL of the spray member SM is upwardly spaced apart from the extending plane BL, the spray member SM and the support ST or the mask MSK may be prevented from interfering each other. In an embodiment, even in a case that a phenomenon that the support ST or the frame FR is lifted off in the third direction DR3 occurs, the spray member SM and the support ST or the frame FR may be prevented from interfering each other, and thus the durability of the mask MSK and the application unit may be secured, and application quality may be uniformly maintained, for example.

Referring to FIG. 5A, a thickness of the support ST in the third direction DR3 and a thickness of the frame FR in the third direction DR3 may be the same as a first thickness D1. The plane BL extending from the position in which he third surface S3 of the support ST and the first roller RL1 contact each other and the plane BL extending from the position in which the first surface S1 of the frame FR and the second roller RL2 contact each other may be the same as the plane (hereinafter, also referred to as reference plane) BL.

However, without being limited to what is illustrated in the drawing, the plane extending from the position in which the third surface S3 of the support ST and the first roller RL1 contact each other and the plane extending from the position in which the first surface S1 of the frame FR and the second roller RL2 contact each other may be different from each other. In an embodiment, one plane may be placed higher than the other plane, for example, but the inventive concept is not limited thereto. However, even in this case, the two planes are all placed lower than the lowermost end UL of the spray member SM.

In an embodiment of the inventive concept, the thickness of the support ST in the third direction DR3 may be the same as the thickness of the frame FR in the third direction DR3.

In this case, the plane extending from the third surface S3 of the support ST may be the same as the plane extending from the first surface S1 of the frame FR. When each plane is equally provided and the application unit SU moves along the second direction DR2, an upper surface of the mask MSK may be moved without being biased to either side. Accordingly, a lift-off phenomenon of the support ST and deformation of the frame FR may be effectively prevented, and thus uniformity of application quality may be secured.

Referring to FIG. 5B, the method for manufacturing a display device in an embodiment of the inventive concept may include an operation of applying an application material RS, e.g., a resin RS onto the mask opening M-OP by the spray member SM of the application unit SU.

The spray member SM may spray the application material RS onto the mask opening M-OP. Specifically, a first spray member SM1 may spray the application material RS to the first opening OP1, a second spray member SM2 may spray the application material RS to the second opening OP2, and a third spray member SM3 may spray the application material RS to the third opening OP3. When the application material RS is sprayed to the first opening OP1, the second opening OP2, and the third opening OP3, at least a portion of the application material RS to be applied may be applied onto at least a portion of the upper surface of the support ST or at least a portion of the upper surface of the frame FR.

Referring to the drawing, the upper surface of a material applied into the mask opening M-OP may be placed over the reference plane BL described above, but may be placed under the reference plane BL without being limited to the drawing, and the inventive concept is not limited thereto.

The application material RS applied into the mask opening M-OP may be applied onto the display panel DP.

It is illustrated that the application material RS is applied onto the display panel DP, but the inventive concept is not limited thereto, and the application material RS may be applied onto a motherboard including a plurality of display panels DP. In this case, the application material RS may be applied through the mask opening M-OP from at least anyone among the first spray member SM1, the second spray member SM2, and the third spray member SM3 described above, and thus be applied only onto a portion of the motherboard. Consequently, the application material RS may be applied only onto some display panels of the plurality of display panels DP.

In addition, a region overlapping the support ST on the motherboard may be a region onto which the application material RS is not applied. The region of the motherboard which overlaps the support ST and onto which the application material RS is not applied may be a dummy region, and may be a region on which scribing is performed.

Unlike a partial region, of the motherboard, which overlaps the support ST and onto which the application material RS is not applied, it is possible for the third spray member SM3 to spray the application material RS to the third opening OP3 (refer to FIG. 5A), so that a resin may be disposed in a partial region, of the motherboard, which overlaps the third opening OP3 (refer to FIG. 5A).

Thereafter, during scribing of a region, of the motherboard, which overlaps the support ST and onto which the application material RS is not applied, a scribing device is supported in a region, of the motherboard, which overlaps the support ST and onto which the application material RS is applied, scribing of the motherboard may be smoothly processed, thereby increasing process efficiency and improving product quality.

A thickness of the application material RS applied onto the mask opening M-OP in an embodiment of the inventive concept may be about 150 micrometers (μm), for example, but an embodiment of the inventive concept is not limited to this value.

Referring to FIGS. 5C and 5D, the method for manufacturing a display device in an embodiment of the inventive concept may include an operation of removing the application unit SU (refer to FIG. 5B) disposed on the mask MSK, and an operation of removing the mask MSK disposed on the mask stage STG1. A portion of the application material RS, which has been applied onto the display panel DP, may be removed in the operation of removing the mask MSK.

The application material RS may be applied into the first opening OP1 (refer to FIG. 5A), the second opening OP2 (refer to FIG. 5A), and the third opening OP3 (refer to FIG. 5A). In addition, the application material RS may be applied onto at least a portion of the first surface S1 of the frame FR and at least a portion of the third surface S3 of the support ST. In the operation of removing the mask MSK, the application material RS applied onto the at least a portion of the first surface S1 of the frame FR and the application material applied onto the at least a portion of the third surface S3 of the support ST may be removed together with the mask MSK.

The application material RS may be removed together with the mask MSK, and a portion where the mask MSK and the application material RS contact each other may be smoothly controlled.

A thickness D2 of the application material RS in the third direction DR3 may be greater than or equal to the first thickness D1 of the mask MSK (refer to FIG. 5A) in the third direction DR3.

Referring to FIG. 5E, the method for manufacturing a display device in an embodiment of the inventive concept may include an operation of curing the application target which has been applied onto the display panel DP.

The display device manufacturing apparatus may include a curing unit HU. Referring to FIG. 5E, the curing unit HU may supply an inner space in which the stage STG2, the mask stage STG1, the display panel DP, and the application material RS having been applied are accommodated. In an embodiment, the curing unit HU may be a chamber, for example. However, the curing unit HU is not limited to a chamber, and may be supplied as various curing devices such as heaters, and the inventive concept is not limited thereto.

The resin may be controlled to have desired properties through curing. A thermal curing method is mentioned in the inventive concept as one method for curing the resin, but the inventive concept is not limited thereto. An ultraviolet (“UV”) curing method may be used, and the inventive concept is not limited thereto.

The second thickness D2 of the application material RS applied onto the display panel DP before curing may be equal to or different from a third thickness D3 of a resin RS' having been applied onto the display panel DP after curing. The second thickness D2 of the application material RS applied onto the display panel DP before curing may be greater than or equal to the third thickness D3 of the cured resin RS' or a thickness target value of the resin.

Here, the application material RS′ after curing may be controlled to have the same shape as that of the application material RS before curing by maintaining the viscosity of the application material RS high.

A display device manufacturing apparatus in an embodiment of the inventive concept ensures thickness uniformity of an application material.

In the above, description has been made with reference to preferred embodiments of the inventive concept, but those skilled in the art or those of ordinary skill in the relevant technical field may understand that various modifications and changes may be made to the inventive concept within the scope not departing from the spirit and the technology scope of the inventive concept described in the claims to be described later. Therefore, the technical scope of the inventive concept is not limited to the contents described in the detailed description of the specification, but should be determined by the claims.

What is claimed is:

1. A display device manufacturing apparatus comprising:
a stage on which a display panel is provided;
a mask provided on the display panel, the mask including:
a frame including:
a first surface; and
a second surface opposed to the first surface and facing the stage, and in which a mask opening penetrating the first surface and the second surface is defined; and
a support disposed in the mask opening and extended to the frame, the support including:
a third surface having a same plane as a plane of the first surface; and
a fourth surface opposed to the third surface; and
an application unit which moves along a direction parallel to a first direction in which the support extends, the application unit including:
a first roller in contact with the third surface,
a second roller in contact with the first surface, and
a spray member which is disposed between the first roller and the second roller in a second direction crossing the first direction, and sprays a resin to the mask opening.

2. The display device manufacturing apparatus of claim 1, wherein a lowermost end of the spray member is spaced apart from planes extending from the first surface and from the second surface.

3. The display device manufacturing apparatus of claim 1, wherein the support overlaps a center portion of the mask opening.

4. The display device manufacturing apparatus of claim 1, wherein the first roller is provided in plural, and the first rollers are arranged along the second direction.

5. The display device manufacturing apparatus of claim 1, wherein the second roller is provided in plural, and the second rollers are disposed apart from each other with the first roller therebetween.

6. The display device manufacturing apparatus of claim 1, wherein the support is arranged in plural,
the first roller is provided in plural, and
the first rollers are arranged along the second direction and respectively contact the supports.

7. The display device manufacturing apparatus of claim 1, wherein the mask further comprises an auxiliary support disposed in the mask opening, extending along the second direction and extended to the frame, and
a width of the auxiliary support in the first direction is equal to or greater than a width of the support in the second direction.

8. The display device manufacturing apparatus of claim 1, wherein the resin sprayed by the spray member overlaps at least a portion of the first surface and at least a portion of the support.

9. The display device manufacturing apparatus of claim 1, wherein the mask comprises metal.

10. The display device manufacturing apparatus of claim 9, wherein at least one of the first roller or the second roller comprises polyimide-based plastic.

11. The display device manufacturing apparatus of claim 1, wherein a thickness of the support in a third direction is equal to a thickness of the frame in the third direction.

12. The display device manufacturing apparatus of claim 1, wherein the spray member is provided in plural, and
the spray members are disposed apart from each other in the second direction with the first roller therebetween.

13. The display device manufacturing apparatus of claim 1, further comprising a curing unit which cures the resin applied to the display panel.

14. The display device manufacturing apparatus of claim 1, further comprising a mask stage which is disposed between the stage and the mask and supports the mask.

15. The display device manufacturing apparatus of claim 14, wherein a stage opening for accommodating the display panel is defined in the mask stage, and the stage opening overlaps the mask opening.

16. A display device manufacturing apparatus comprising:
a mask including:
a frame in which a mask opening penetrating a first surface and a second surface facing each other is defined; and
a support which is disposed in the mask opening, is extended to the frame, extends along a first direction and divides the mask opening into a first opening and a second opening arranged along a second direction crossing the first direction; and
an application unit which moves along the first direction on the first surface of the mask, the application unit including:
a first roller in contact with one surface of the support,
a first spray member overlapping the first opening, and
a second spray member spaced apart from the first spray member in the second direction with the first roller therebetween, and overlapping the second opening.

17. The display device manufacturing apparatus of claim 16, wherein the application unit further comprises a plurality of second rollers each being in contact with the second surface of the frame, and spaced apart from each other in the second direction with the first spray member and the second spray member therebetween.

18. The display device manufacturing apparatus of claim 16, wherein a lowermost end of each of the first and second spray members is spaced apart from planes extending from the one surface of the support and from the second surface of the frame.

19. The display device manufacturing apparatus of claim 16, wherein the support and the first roller are each provided in plural.

20. The display device manufacturing apparatus of claim 16, wherein the mask further comprises an auxiliary support disposed in the mask opening, extending along the second direction and extended to the frame, and
a width of the auxiliary support in the first direction is equal to or greater than a width of the support in the second direction.
